(19) United States
(12) Patent Application Publication
(10) Pub. No.: US 2010/0040103 A1
(43) Pub. Date: Feb. 18, 2010

(54) SEMICONDUCTOR DEVICE

(75) Inventors: Katsumi Kishino, Tokyo (JP); Ichiro Nomura, Tokyo (JP); Koshi Tamamura, Tokyo (JP); Kunihiko Tasai, Kanagawa (JP); Tsunenori Asatsuma, Kanagawa (JP); Hiroshi Nakajima, Kanagawa (JP); Hitoshi Nakamura, Tokyo (JP); Sumiko Fujisaki, Tokyo (JP); Takeshi Kikawa, Tokyo (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignees: HITACHI, LTD, Tokyo (JP); SOPHIA SCHOOL CORPORATION, Tokyo (JP); SONY CORPORATION, Tokyo (JP)

(21) Appl. No.: 12/536,210

(22) Filed: Aug. 5, 2009

(30) Foreign Application Priority Data
Aug. 12, 2008 (JP) 2008-207863

(51) Int. Cl. H01S 5/20

(52) U.S. Cl. 372/45.012

(57) ABSTRACT

The present invention provides a semiconductor device including: a semiconductor layer including an n-type first cladding layer, an n-type second cladding layer, an active layer, a p-type first cladding layer, and a p-type second cladding layer in this order on an InP substrate. The n-type first cladding layer and the n-type second cladding layer satisfy formulas (1) to (4) below, or the p-type first cladding layer and the p-type second cladding layer satisfy formulas (5) to (8) below.

1×10¹⁷ cm⁻³≦N1≦1×10²⁰ cm⁻³ (1)

N1>N2 (2)

D1>D2 (3)

Ec1<Ec3<Ec2 (4)

1×10¹⁷ cm⁻³≦N4≦10²⁰ cm⁻³ (5)

N3<N4 (6)

D3<D4 (7)

Ev1<Ev3<Ev2 (8)

### BACKGROUND OF THE INVENTION

1. Field of the Invention

The present invention relates to a semiconductor device including an n-type semiconductor layer and a p-type semiconductor layer on an InP substrate.

2. Description of the Related Art

A laser diode (LD) is used as a light source in an optical disk unit such as a CD (compact disk), a DVD (digital versatile disk) or a blu-ray disk. In addition to the application as above, the laser diode is applied in various fields such as optical communication, solid laser excitation, material processing, a sensor, a measurement unit, medical care, a printing machine, and a display. A light emitting diode (LED) is applied in fields such as an indication lamp in electric appliance, infrared communication, a printing machine, a display and an illumination lamp.

However, in the LED, efficiency in green is not so high in comparison with those of other colors, although green is the color to which human beings have the highest spectral sensitivity. On the other hand, in the LD, practicable properties are not obtained in a visible light range from pure blue (480 nm or a little more) to orange (600 nm or a little more). For example, it is reported by E. Kato et al. that, in a blue-green LD (approximately 500 nm) which is formed by stacking a II-VI group compound semiconductor on a GaAs substrate, room temperature continuous-wave operation for approximately 400 hours with 1 mW is realized (“Significant progress in II-VI blue-green laser diode lifetime” by E. Kato et al., Electronics Letters 5^{th}, February 1998, Vol. 34, No. 3, pp. 282-284). However, further properties are not yet obtained in this material system. It is considered that this is because of the physical properties of the material that crystal defects easily occur and move.

In the II-VI group compound semiconductor, in general, p-type conductivity is not easily controlled. In particular, there is a tendency that p-type carrier concentration is reduced with an increase in energy gap. For example, an energy gap is increased with an increase in a composition ratio of Mg in ZnMgSSe used as a p-type cladding layer in “Significant progress in II-VI blue-green semiconductor device life time” by E. Kato et al., Electronics Letters 5^{th}, February 1998, Vol. 34, No. 3, pp. 282-284. However, when the energy gap is approximately 3 eV or more, the p-type carrier concentration is reduced to a value smaller than 1×10¹⁷ cm⁻³, and it is not easy to use ZnMgSSe as the p-type cladding layer. The reason for this is considered as follows. Although there are atoms of nitrogen (N) as a p-type dopant in ZnMgSSe, many of the atoms are located in an interstitial site except a VI group site, and do not become carriers. This means that an activation rate of the p-type dopant is low (remarkably lower than 1%). Moreover, it is considered that many atoms located in the interstitial site may be a major cause of generation of the crystal defects.

In “Significant progress in II-VI blue-green semiconductor device life time” by E. Kato et al., Electronics Letters 5^{th}, February 1998, Vol. 34, No. 3, pp. 282-284, since ZnCdSe used as an active layer is not perfectly lattice-matched to a GaAs substrate, there is deformation in ZnCdSe. Generally, in a photo-emission device and a photo-reception device, due to influence of heat, electric conduction, deformation or the like, defect is transmitted and diffused from a region which has the largest number of crystal defects and the defect reaches the active layer. This results in deterioration of the device, and reduction in life time of the device. Thus, in the case where the active layer has deformation as described in “Significant progress in II-VI blue-green semiconductor device life time” by E. Kato et al., Electronics Letters 5^{th}, February 1998, Vol. 34, No. 3, pp. 282-284, when crystal defect occurs in a p-type cladding layer or the like, there is a high possibility that the device is deteriorated due to the crystal defect.

For this reason, the inventors and some research groups from home and abroad focus on a II-VI group compound semiconductor of MgₓZn_{y}Cd_{1-x-y}Se (0≦x≦1, 0≦y≦1, 0<1-x -y<1) as candidate material for forming an optical device which emits light from yellow to green, and conduct research and development (“Molecular beam epitaxial growth of high quality Zn1-xCdxSe on InP substrates” by N. Dai et al., Appl. Phys. Lett., 66, 2742 (1995), and “Molecular Beam Epitaxial Growth of MgZnCdSe on (100) InP Substrates” by T. Morita et al., J. Electron. Mater., 25, 425 (1996)). When each of composition x and composition y satisfies the relational expression below, MgₓZn_{y}Cd_{1-x-y}Se (hereafter, simply referred to as “MgZnCdSe”) is lattice-matched to InP, and the energy gap in MgₓZn_{y}Cd_{1-x-y}Se is controllable from 2.1 eV to 3.6 eV by changing each of composition x and composition y from (x=0, y=0.47) to (x=0.8, y=0.17).

y=0.47−0.37x.

Composition x is 0 or more and 0.8 or less.
Composition y is 0.17 or more and 0.47 or less.

In the above composition range, a forbidden band generally indicates direct transition type, and, when the energy gap is converted to the wavelength, the wavelength is from 590 nm (orange) to 344 nm (ultraviolet). Thus, it is indicated that an active layer and a cladding layer in a light emitting device which emits light from yellow to green is realized by only changing composition x and composition y in MgZnCdSe.

In fact, by T. Morita et al., photoluminescence measurement is performed to MgZnCdSe which is grown on an InP substrate by molecular beam epitaxy (MBE) method. It is reported that, in MgZnCdSe with varied composition x and composition y, superior light emission properties are obtained with a peak wavelength from 571 nm to 397 nm (“Molecular Beam Epitaxial Growth of MgZnCdSe on (100) InP Substrates” by T. Morita et al., J. Electron. Mater., 25, 425 (1996)).

It is reported by L. Zeng et al. that, in a quantum well structure formed by using MgZnCdSe, laser oscillation by light excitation is realized in each wavelength band of red, green, and blue (“Red-green-blue photopumped lasing from ZnCdMgSe/ZnCdSe quantum well laser structure grown on InP” by L. Zeng et al., Appl. Phys. Lett., 72, 3136 (1998)).

On the other hand, in an LD which is configured with only MgZnCdSe, laser oscillation by current drive has not been reported so far. It is considered that the major reason for this is difficulty to control the p-type conductivity by doping impurities of MgZnCdSe.

Thus, while using MgZnCdSe as the n-type cladding layer, the inventors have conducted a study to search optimal material for the active layer and the p-type cladding layer. As a result, 77K oscillation in an yellow-green LD at 560 nm is realized by using ZnₛCd₁₋ₛSe (0≦s≦1) (hereafter, simply described as “ZnCdSe”) as the active layer, and using a stacked structure of MgSe/BeZnTe as the p-type cladding layer in which a BeₜZn₁₋ₜTe layer (0≦t≦1) (hereafter, simply described as “BeZnTe”) and an MgSe layer are alternately stacked. Here, 77K oscillation means that the light emitting device is oscillated while being cooled to 77K. Instead of ZnCdSe, by using BeᵤZn₁₋ᵤSe_{w}Te_{1-w}, (0≦u≦1, 0≦w≦1) (hereafter, simply described as “BeZnSeTe”) as the active layer, single-peak light emission from orange to yellow-green at 594 nm, 575 nm, and 542 nm is observed, and light emission at a room-temperature for 5000 hours or more is realized in the LED of 575 nm.

Moreover, the inventors have manufactured an LED device in which an n-cladding layer has a single-layer structure of MgZnCdSe or a superlattice structure of MgSe/ZnCdSe and the active layer has a single-layer structure of BeZnSeTe, and have studied in detail mechanism of the light emission. As a result, it is understood that dependency on driving current is large in a light emission wavelength, and it is indicated that light emission of Type II is generated in a hetero interface from the n-type cladding layer to the vicinity of the active layer.

Next, as the n-type cladding layer and the p-type cladding layer which are lattice-matched to InP, the inventors have developed a guideline that the n-type cladding layer and the p-type cladding layer have an energy gap and refractive index with which carrier confinement and light confinement are possible, and doping to obtain sufficient carrier concentration is possible.

As a result, the inventors have discovered that the above conditions are satisfied by mainly using MgZnSeTe as the n-type cladding layer, and mainly using BeMgZnTe as the p-type cladding layer. Moreover, the inventors have proposed a laser diode capable of green oscillation by using the n-type cladding layer and the p-type cladding layer described above, and BeZnSeTe as material for the active layer.

### SUMMARY OF THE INVENTION

After that, the inventors have grown the above material through crystal growth by using MBE method, and have performed evaluation. As a result, in the n-type cladding layer containing MgZnSeTe as a major component, it is understood that refractive index which is sufficient for the light confinement is obtained, and an electron barrier which is sufficient for the carrier confinement is obtained. However, at this point, it is understood that the carrier concentration of only approximately 1×10¹⁷ cm⁻³ is obtained, and this is still insufficient for a carrier conductivity, although there is a possibility that the growth conditions are not perfectly optimized. Moreover, it is understood that it is difficult to grow the cladding layer through crystal growth to have the thickness necessary for the confinement (for example, thickness of approximately 1 μm) while crystalline properties are maintained in favorable conditions. On the other hand, in the p-type cladding layer containing BeMgZnTe as a major component, it is understood that the carrier concentration sufficient for the carrier conductivity (1×10¹⁸ cm⁻³ or more) is obtained, and the refractive index sufficient for the light confinement is obtained. However, at this point, it is understood that it is difficult to grow the cladding layer through crystal growth to have the thickness necessary for the confinement (for example, thickness of approximately 1 μm) while crystalline properties are maintained in favorable conditions, and only a hole barrier which is insufficient for the carrier confinement is obtained.

In view of the foregoing, it is desirable to provide a semiconductor device including an n-type cladding layer which has properties desired in an n-type cladding layer, or a p-type cladding layer which has properties desired in a p-type cladding layer.

According to an embodiment of the present invention, there is provided a semiconductor device including: a semiconductor layer including an n-type first cladding layer, an n-type second cladding layer, an active layer, a p-type first cladding layer, and a p-type second cladding layer in this order on an InP substrate. The n-type first cladding layer and the n-type second cladding layer satisfy formulas (1) to (4) below, or the p-type first cladding layer and the p-type second cladding layer satisfy formulas (5) to (8) below.

1×10¹⁷ cm⁻³≦N1≦1×10²⁰ cm⁻³ (1)

N1>N2 (2)

D1>D2 (3)

Ec1<Ec3<Ec2 (4)

1×10¹⁷ cm⁻³≦N4≦10²⁰ cm⁻³ (5)

N3<N4 (6)

D3<D4 (7)

Ev1<Ev3<Ev2 (8)

Here, N1 is n-type carrier concentration of the n-type first cladding layer, N2 is n-type carrier concentration of the n-type second cladding layer, D1 is layer thickness of the n-type first cladding layer, D2 is layer thickness of the n-type second cladding layer, Ec1 is a bottom of a conduction band or a bottom of a sub-level of a conduction band in the n-type first cladding layer, Ec2 is a bottom of a conduction band or a bottom of a sub-level of a conduction band in the n-type second cladding layer, Ec3 is a bottom of a conduction band or a bottom of a sub-level of a conduction band in the active layer, N3 is p-type carrier concentration of the p-type first cladding layer, N4 is p-type carrier concentration of the p-type second cladding layer, D3 is layer thickness of the p-type first cladding layer, D4 is layer thickness of the p-type second cladding layer, Ev1 is a top of a valence band or a top of a sub-level of a valence band in the p-type first cladding layer, Ev2 is a top of a valence band or a top of a sub-level of a valence band in the p-type second cladding layer, and Ev3 is a top of a valence band or a top of a sub-level of a valence band in the active layer.

In the semiconductor device according to the embodiment of the present invention, the n-type cladding layer or the p-type cladding layer is separated to two layers depending on major functions. For example, in the case where the n-type cladding layer is separated to two layers depending on major functions, in one of the n-type cladding layers (n-type first cladding layer), the n-type carrier concentration is higher than that of the other of the n-type cladding layers (n-type second cladding layer), and the layer thickness is larger than that of the n-type second cladding layer. Thereby, the carrier conductivity of the whole n-type cladding layer is maintained. In the n-type second cladding layer, the bottom of the conduction band or the bottom of the sub-level of the conduction band is higher than the bottom of the conduction band or the bottom of the sub-level of the conduction band in the active layer. Thereby, the electron barrier which is sufficient for the carrier confinement is maintained, and light emission of type II is suppressed. For example, in the case where the p-type cladding layer is separated to two layers depending on major functions, in one of the p-type cladding layers (p-type second cladding layer), the p-type carrier concentration is higher than that of the other of the p-type cladding layers (p-type first cladding layer), and the layer thickness is larger than that of the p-type first cladding layer. Thereby, the p-type carrier concentration which is sufficient for the carrier conductivity is maintained. In the p-type first cladding layer, the top of the valence band or the top of the sub-level of the valence band is lower than the top of the valence band or the top of the sub-level of the valence band in the active layer. Thereby, the hole barrier which is sufficient for the carrier confinement is maintained, and the light emission of type II is suppressed.

In the semiconductor device according to the embodiment of the present invention, since the n-type cladding layer or the p-type cladding layer is separated to two layers depending on major functions (two types of the carrier conductivity, and the carrier confinement and suppression of the light emission of type II), it is possible that all the properties of the carrier conductivity, the carrier confinement, suppression of the light emission of type II, and the light confinement are set to values appropriate for the n-type cladding layer and the p-type cladding layer. As a result, it is possible to realize the semiconductor device including the n-type cladding layer which has properties desired in an n-type cladding layer, or the p-type cladding layer which has properties desired in a p-type cladding layer.

Other and further objects, features and advantages of the invention will appear more fully from the following description.

### BRIEF DESCRIPTION OF THE DRAWINGS

FIG. 1 is a cross-sectional configuration view of a laser diode according to an embodiment of the present invention.

FIG. 2 is a concept view for explaining a band structure of the laser diode of FIG. 1.

### DETAILED DESCRIPTION OF THE PREFERRED EMBODIMENT

A preferred embodiment of the present invention will be described in detail with reference to the accompanying drawings.

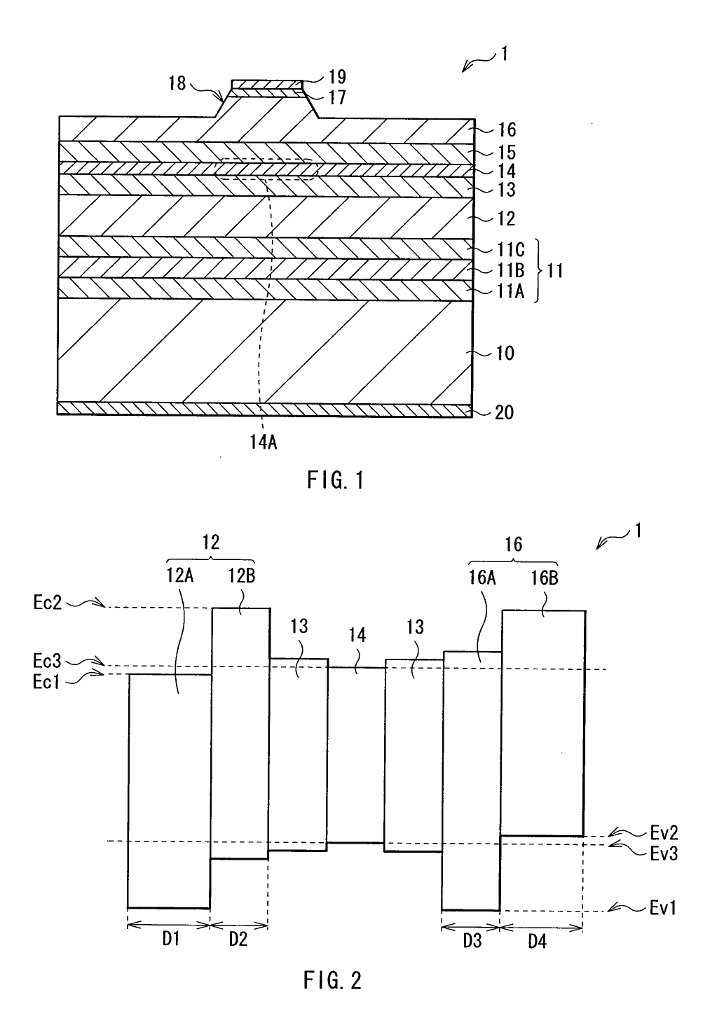

FIG. 1 indicates the cross-sectional configuration of a laser diode 1 (semiconductor device) according to an embodiment of the present invention. FIG. 2 schematically indicates an example of a band structure of each layer in FIG. 1. The laser diode 1 is formed by epitaxial growth method, for example, molecular beam epitaxy (MBE) method and metal organic chemical vapor deposition (MOCVD) method or metal organic vapor phase epitaxy (MOVPE) method. The laser diode 1 is formed by depositing and growing a crystal film while maintaining a specific crystallographic orientation relationship between crystal of a substrate 10 and the crystal film.

The laser diode 1 has the configuration in which a buffer layer 11, an n-type cladding layer 12, an n-side guide layer 13, an active layer 14, a p-side guide layer 15, a p-type cladding layer 16, and a contact layer 17 are stacked in this order on one surface side of the substrate 10.

The substrate 10 is an InP substrate. The buffer layer 11 is formed on the surface of the substrate 10 to improve crystal growth potential of each semiconductor layer from the n-type cladding layer 12 to the contact layer 17, and includes, for example, buffer layers 11A, 11B, and 11C stacked in this order from the substrate 10 side. Here, the buffer layer 11A is made of, for example, Si-doped n-type InP. The buffer layer 11B is made of, for example, Si-doped n-type InGaAs. The buffer layer 11C is made of, for example, Cl-doped n-type ZnCdSe.

The n-type cladding layer 12 has the configuration in which an n-type first cladding layer 12A and an n-type second cladding layer 12B are stacked in this order from an opposite side of the active layer 14 (in the embodiment, from the substrate 10 side).

The n-type first cladding layer 12A mainly maintains carrier (electron) conductivity of the n-type cladding layer 12 in relation between the n-type first cladding layer 12A and the n-type second cladding layer 12B. In the n-type first cladding layer 12A, n-type carrier concentration is a value within a range from 1×10¹⁷ cm⁻³ to 1×10²⁰cm⁻³, and the n-type carrier concentration is a value higher than that of the n-type carrier concentration of the n-type second cladding layer 12B. Moreover, the thickness of the n-type first cladding layer 12A is larger than that of the n-type second cladding layer 12B. The energy gap of the n-type first cladding layer 12A is larger than that of each of the n-side guide layer 13 and the active layer 14. The refractive index of the n-type first cladding layer 12A is smaller than that of each of the n-side guide layer 13 and the active layer 14. A bottom of a conduction band or a bottom of a sub-level of a conduction band in the n-type first cladding layer 12A is lower than the bottom of the conduction band or the bottom of the sublevel of the conduction band in the active layer 14.

The n-type first cladding layer 12A has, for example, a single-layer structure mainly containing Mgₓ₁Znₓ₂Cd₁₋ₓ₁₋ₓ₂Se (0<x1<1, 0<x2<1, 0<1−x1−x2<1), or has a stacked structure mainly containing superlattice of MgSe/Znₓ₃Cd₁₋ₓ₃Se (0<x3<1).

The n-type second cladding layer 12B mainly maintains carrier (electron) confinement of the n-type cladding layer 12 in relation between the n-type first cladding layer 12A and the n-type second cladding layer 12B, and controls light emission of type II. In the n-type second cladding layer 12B, the bottom of the conduction band or the bottom of the sub-level of the conduction band is higher than the bottom of the conduction band or the bottom of the sub-level of the conduction band in each of the n-side guide layer 13 and the active layer 14. The energy gap of the n-type second cladding layer 12B is larger than that of each of the n-side guide layer 13 and the active layer 14. The refractive index of the n-type second cladding layer 12B is smaller than that of each of the n-side guide layer 13 and the active layer 14. The n-type carrier concentration of the n-type second cladding layer 12B is a value lower than that of the n-type carrier concentration of the n-type first cladding layer 12A. The thickness of the n-type second cladding layer 12B is smaller than that of the n-type first cladding layer 12A. A top of a valence band or a top of a sub-level of a valence band in the n-type second cladding layer 12B is lower than the top of the valence band or the top of the sub-level of the valence band in each of the n-side guide layer 13 and the active layer 14.

The n-type second cladding layer 12B has, for example, a single-layer structure mainly containing Mgₓ₄Zn₁₋ₓ₄Seₓ₅Te₁₋ₓ₅ (0<x4<1, 0.5<x5<1), or a stacked structure mainly containing superlattice of MgSe/Mgₓ₆Zn₁₋ₓ₆Seₓ₇Te₁₋ₓ₇ (0<x6<1, 0.5<x7<1).

Here, in the case where the n-type first cladding layer 12A or the n-type second cladding layer 12B include superlattice, it is possible to change (control) the effective energy gap by adjusting material (composition ratio) for each layer and the thickness of each layer included in the superlattice. Also in the case where each semiconductor layer which will be described later includes superlattice, it is possible to change (control) the effective energy gap by adjusting material (composition ratio) for each layer and the thickness of each layer included in the superlattice. As n-type impurities contained in the n-type cladding layer 12, for example, there is Cl.

The descriptions made for the n-type first cladding layer 12A and the n-type second cladding layer 12B may be expressed by formulas (1) to (4) below.

1×10¹⁷ cm⁻³≦N1≦1×10²⁰ cm⁻³ (1)

N1>N2 (2)

D1>D2 (3)

Ec1<Ec3<Ec2 (4)

Here, N1 is the n-type carrier concentration of the n-type first cladding layer 12A. N2 is the n-type carrier concentration of the n-type second cladding layer 12B. D1 is the layer thickness of the n-type first cladding layer 12A. D2 is the layer thickness of the n-type second cladding layer 12B. Ec1 is the bottom of the conduction band or the bottom of the sub-level of the conduction band in the n-type first cladding layer 12A. Ec2 is the bottom of the conduction band or the bottom of the sub-level of the conduction band in the n-type second cladding layer 12B. Ec3 is the bottom of the conduction band or the bottom of the sub-level of the conduction band in the active layer 14.

The energy gap of the n-side guide layer 13 is larger than that of the active layer 14. The refractive index of the n-side guide layer 13 is smaller than that of the active layer 14. The bottom of the conduction band or the bottom of the sub-level of the conduction band in the n-side guide layer 13 is higher than the bottom of the conduction band or the bottom of the sub-level of the conduction band in active layer 14. It is preferable that the top of the valence band or the top of the sub-level of the valence band in the n-side guide layer 13 is lower than the top of the valence band or the top of the sub-level of the valence band in the active layer 14.

The n-side guide layer 13 has, for example, a stacked structure mainly containing superlattice of MgSe/Beₓ₁₉Zn₁₋ₓ₁₉Seₓ₂₀Te₁₋ₓ₂₀ (0<x19<1, 0<x20<1). However, in the case where the n-side guide layer 13 contains the above-described superlattice, it is preferable that both of the MgSe layer and the Beₓ₁₉Zn₁₋ₓ₁₉Seₓ₂₀Te₁₋ₓ₂₀ layer are undoped. In the specification of the present invention, “undoped” means that dopant is not supplied to a semiconductor layer when manufacturing the semiconductor layer. It is the concept also including the case where impurities are not contained at all in the semiconductor layer, and the case where impurities diffused from other semiconductor layers or the like are slightly contained in the semiconductor layer.

The active layer 14 mainly contains a II-VI group compound semiconductor having the energy gap corresponding to the desired light emission wavelength (for example, wavelength of a green band). For example, the active layer 14 has a single-layer structure mainly containing Beₓ₁₃Zn₁₋ₓ₁₃Seₓ₁₄Te₁₋ₓ₁₄(0<x13<1, 0<x14<1), a stacked structure mainly containing superlattice of MgSe/Beₓ₁₅Zn₁₋ₓ₁₅Seₓ₁₆Te₁₋ₓ₁₆(0<x15<1, 0<x16<1), or a stacked structure mainly containing superlattice of ZnSe/Beₓ₁₇Zn₁₋ₓ₁₇Seₓ₁₈Te₁₋ₓ₁₈ (0<x17<1, 0<x18<1). It is preferable that the whole active layer 14 is undoped.

In the active layer 14, a region facing a ridge 18 which will be described later is a light emission region 14A. The light emission region 14A has a stripe width with a size equal to that of the bottom of the ridge 18 facing the light emission region 14A, and corresponds to a current injection region to which current confined in the ridge 18 is injected.

The p-side guide layer 15 has the energy gap larger than that of the active layer 14. The refractive index of the p-side guide layer 15 is smaller than that of the active layer 14. The top of the valence band or the top of the sub-level of the valence band in the p-side guide layer 15 is lower than the top of the valence band or the top of the sub-level of the valence band in the active layer 14. It is preferable that the bottom of the conduction band or the bottom of the sub-level of the conduction band in the p-side guide layer 15 is higher than the bottom of the conduction band or the bottom of the sub-level of the conduction band in the active layer 14.

The p-side guide layer 15 has, for example, a stacked structure mainly containing superlattice of MgSe/Beₓ₂₁Zn₁₋ₓ₂₁Seₓ₂₂Te₁₋ₓ₂₂ (0<x21<1, 0<x22<1). However, in the case where the p-side guide layer 15 contains the superlattice as described above, it is preferable that both of the MgSe layer and the Beₓ₂₁Zn₁₋ₓ₂₁Seₓ₂₂Te₁₋ₓ₂₂ layer are undoped.

The p-type cladding layer 16 has the configuration in which a p-type first cladding layer 16A, and a p-type second cladding layer 16B are stacked in this order from the active layer 14 side.

The p-type first cladding layer 16A mainly maintains carrier (hole) confinement of the p-type cladding layer 16 in relation between the p-type first cladding layer 16A and the p-type second cladding layer 16B, and controls light emission of type II. The top of the valence band or the top of the sub-level of the valence band in the p-type first cladding layer 16A is lower than the top of the valence band or the top of the sub-level of the valence band in each of the active layer 14, the p-side guide layer 15, and the p-side second cladding layer 16B. The bottom of the conduction band or the bottom of the sub-level of the conduction band in the p-type first cladding layer 16A is higher than the bottom of the conduction band or the bottom of the sub-level of the conduction band in each of the active layer 14 and the p-side guide layer 15. The energy gap of the p-type first cladding layer 16A is larger than that of each of the active layer 14 and the p-side guide layer 15. The refractive index of the p-type first cladding layer 16A is smaller than that of each of the active layer 14 and the p-side guide layer 15. The p-type carrier concentration of the p-type first cladding layer 16A is a value lower than that of the p-type carrier concentration of the p-type second cladding layer 16B. The thickness of the p-type first cladding layer 16A is smaller than that of the p-type second cladding layer 16B.

The p-type first cladding layer 16A has, for example, a stacked structure mainly containing superlattice of MgSe/Beₓ₈Zn₁₋ₓ₈Te (0<x8<1). It is preferable that the MgSe layer is undoped.

The p-type second cladding layer 16B mainly maintains the carrier (hole) conductivity of the p-type cladding layer 16 in relation between the p-type first cladding layer 16A and the p-type second cladding layer 16B. In the p-type second cladding layer 16B, the p-type carrier concentration is a value within a range from 1×10¹⁷ cm⁻³ to 1×10²⁰cm⁻³, and the p-type carrier concentration is a value higher than that of the p-type carrier concentration of the p-type first cladding layer 16B. Moreover, the thickness of the p-type second cladding layer 16B is larger than that of the p-type first cladding layer 16A. The energy gap of the p-type second cladding layer 16B is larger than that of each of the active layer 14 and the p-side guide layer 15. The refractive index of the p-type second cladding layer 16B is smaller than that of each of the active layer 14 and the p-side guide layer 15. The top of the valence band or the top of the sub-level of the valence band in the p-type second cladding layer 16B is higher than the top of the valence band or the top of the sub-level of the valence band in the active layer 14.

The p-type second cladding layer 16B has, for example, a stacked structure mainly containing superlattice of Beₓ₉Mg₁₋ₓ₁₉Te/Beₓ₁₀Zn₁₋ₓ₁₀Te (0<x9<1, 0<x10<1), or has a single-layer structure mainly containing Beₓ₁₁Mgₓ₁₂Zn₁₋ₓ₁₁₋ₓ₁₂Te (0<x11<1, 0<x12<1, 0<1−x11−x12<1).

As p-type impurities contained in the p-type cladding layer 16 (and the contact layer 17 which will be described below), for example, there is N, P, O, As, Sb, Li, Na or K.

The descriptions made for the p-type first cladding layer 16A and the p-type second cladding layer 16B may be expressed by formulas (5) to (8) below.

1×10¹⁷ cm⁻³≦N4≦10²⁰ cm⁻³ (5)

N3<N4 (6)

D3<D4 (7)

Ev1<Ev3<Ev2 (8)

Here, N3 is the p-type carrier concentration of the p-type first cladding layer 16A. N4 is the p-type carrier concentration of the p-type second cladding layer 16B. D3 is the layer thickness of the p-type first cladding layer 16A. D4 is the layer thickness of the p-type second cladding layer 16B. Ev1 is the top of the valence band or the top of the sub-level of the valence band in the p-type first cladding layer 16A. Ev2 is the top of the valence band or the top of the sub-level of the valence band in the p-type second cladding layer 16B. Ev3 is the top of the valence band or the top of the sub-level of the valence band in the active layer 14.

The contact layer 17 has, for example, the configuration in which p-type BeZnTe and p-type ZnTe are alternately stacked.

In the laser diode 1, as described above, the stripe-shaped ridge 18 extending in an axis direction is formed in the upper part of the p-type cladding layer 16 and the contact layer 17. This ridge 18 limits the current injection region in the active layer 14.

A p-side electrode 19 is formed on the surface of the ridge 18. An n-side electrode 20 is formed on the rear surface of the substrate 10. The p-side electrode 19 has, for example, the configuration in which Pd, Pt, and Au are stacked in this order on the contact layer 17, and is electrically connected to the contact layer 17. The n-side electrode 20 has, for example, the configuration in which alloy of Au and Ge, Ni, and Au are stacked in this order on the rear surface of the substrate 10, and is electrically connected to the substrate 10. The n-side electrode 20 is fixed to the surface of a submount (not illustrated in the figure) supporting the laser diode 1. Moreover, the n-side electrode 20 is fixed to the surface of a heatsink (not illustrated in the figure) through the submount.

It is preferable that the n-type first cladding layer 12A, the n-type second cladding layer 12B, the n-side guide layer 13, the active layer 14, the p-side guide layer 15, the p-type first cladding layer 16A, and the p-type second cladding layer 16B described above are lattice-matched to the substrate 10. Here, since the substrate 10 is the InP substrate, it is preferable that the other layers except the substrate 10 are made of material having a composition ratio which is lattice-matched to InP. As the material in II-VI group compound semiconductor, which is lattice-matched to InP, for example, there is material indicated in Table 1.

TABLE 1

| General formula | Material lattice-matched to InP | Energy gap (eV) |
|---|---|---|
| MgZnCdSe | Mg_{0.33}Cd_{0.33}Zn_{0.34}Se | 2.64 |
| ZnCdSe | Zn_{0.48}Cd_{0.52}Se | 2.1 |
| MgZnSeTe | Mg_{0.6}Zn_{0.4}Se_{0.85}SeTe_{0.15} | 3.0 |
| BeZnTe | Be_{0.48}Zn_{0.52}Te | 3.12 (point Γ) |
| BeMgTe | Be_{0.36}Mg_{0.64}Te | 3.7 |
| BeZnSeTe | Be_{0.13}Zn_{0.87}Se_{0.40}Te_{0.60} | 2.33 |

Here, for example, the value of the energy gap of Be_{0.36}Mg_{0.64}Te which is lattice-matched to InP is obtained by interpolating a value of the energy gap of each of BeTe and MgTe which are binary mixed crystal. Here, the boeing effect seen more or less in ternary mixed crystal is not considered. The boeing effect is also not considered in a value of the energy gap in other ternary or quaternary mixed crystal indicated in Table 1.

In Be_{0.48}Zn_{0.52}Te which is lattice-matched to InP, the direct transition energy gap at the point F may be estimated as approximately 3.12 eV. Thus, depending on the combination ratio of the layer thickness in the superlattice, the value of the energy gap of the superlattice of Be_{0.36}Mg_{0.64}Te/Be_{0.48}Zn_{0.52}Te may be a value between 3.12 eV and 3.7 eV.

Depending on the combination ratio of the layer thickness in the superlattice, the value of the energy gap of the superlattice of MgSe/Be_{0.48}Zn_{0.52}Te may be a value between 3.12 eV and 3.6 eV. Depending on the combination ratio of the layer thickness in the superlattice, the value of the energy gap of the superlattice of MgSe/Mg_{0.6}Zn_{0.4}Se_{0.85}SeTe_{0.15} may be a value between 3.0 eV and 3.6 eV. Depending on the combination ratio of the layer thickness in the superlattice, the value of the energy gap of the superlattice of MgSe/Zn_{0.48}Cd_{0.52}Se may be a value between 2.1 eV and 3.6 eV.

On the other hand, for example, in the case where the single-layer structure mainly containing Beₓ₁₃Zn₁₋ₓ₁₃Seₓ₁₄Te₁₋ₓ₁₄ is used as the active layer 14, the value of the energy gap of the active layer 14 may be a value of the energy gap (2.06 eV to 2.58 eV) corresponding to the wavelength within the range from orange (600 nm) to blue-green (480 nm), under the condition where the active layer 14 is lattice-matched to InP. Accordingly, in the case where the superlattice described above as an example is used for the n-type first cladding layer 12A, the n-type second cladding layer 12B, the n-side guide layer 13, the p-side guide layer 15, the p-type fist cladding layer 16A, and the p-type second cladding layer 16B, it is possible that the energy gap larger than that of the active layer 14 is produced while the n-type first cladding layer 12A, the n-type second cladding layer 12B, the n-side guide layer 13, the p-side guide layer 15, the p-type fist cladding layer 16A, and the p-type second cladding layer 16B are lattice-matched to InP.

It is described that, although MgSe and MgTe have the same level of hygroscopicity in the air, when the composition ratio of Mg in CdMgTe is 75% or less, the structure of CdMgTe is a zinc-blende (ZB) structure, and oxidation reaction does not occur (refer to J. Appl. Phys. by J. M. Hartmann et al., 80, 6257 (1996)). On the other hand, BeMgTe is lattice-matched to InP when the composition ratio of Mg in BeMgTe is approximately 64%, and the composition ratio of Mg at this time is sufficiently smaller than 75%. Therefore, it is thought that Be_{0.36}Mg_{0.64}Te which is lattice-matched to InP has sufficient durability to oxidation and hygroscopicity in comparison with MgSe. Similarly, it is thought that Mg_{0.33}Cd_{0.33}Zn_{0.34}Se and Mg_{0.6}Zn_{0.4}Se_{0.85}Te_{0.15} have the sufficient durability to oxidation and hygroscopicity in comparison with MgSe.

In the embodiment, MgSe is not used in the p-type second cladding layer 16B, which has the large p-type carrier concentration and relates to the electric conductivity. Thereby, there is no risk that the electric conductivity is reduced because of deterioration due to oxidation and hygroscopicity in the p-type second cladding layer 16B.

It is known from experience that Be and Se have high reactivity with each other, and there is a possibility that BeSe is formed in the interface of the superlattice of MgSe/BeZnTe of the related art. However, for example, it is possible to control formation of BeSe by arranging Be and Se not to be in direct contact with each other, for example, by arranging Zn atoms in the interface on the MgSe side in the BeZnTe layer. Moreover, it is possible to form the above-described atom arrangement by using shutter operation in an MBE unit.

When there are Se and Te at the same time, it is concerned that Se is preferentially combined with II group and a phenomenon occurs that Te hardly enters, a deposition phenomenon of Se and Te occurs, or the like. However, for this issue, for example, it is also possible to control occurrence of competition reaction or separation deposition between Se and Te, or the like, by using shutter operation in an MBE unit leading to that there are not SE and TE at the same time.

In Be chalcogenide material, a Be ion has extremely small ion radius and the ratio of covalent bonding is high as a result, in comparison with other VI group except oxygen (Se, Te, or the like). It is said that intensity of crystal itself is high, and occurrence and transmission of a defect such as dislocation is suppressed. By forming the superlattice structure of BeZnTe/BeMgTe, more effects are expected in comparison with the case of the related art where the superlattice structure of BeZnTe/MgSe is used. In the superlattice structure of BeZnTe/BeMgTe, since the both layers of BeZnTe and BeMgTe in the superlattice structure contain Be, it is expected that the transmission of the crystal defect is reduced.

The laser diode 1 having such a configuration may be manufactured, for example, as described below.

Each semiconductor layer described above is manufactured through crystal-growth by using two molecular beam epitaxy (MBE) units. After the surface of the substrate 10 of InP is appropriately processed, the substrate 10 is set in the MBE unit. Next, the substrate 10 is housed in a preparation room for sample change, and the preparation room is vacuumed to 10⁻³ Pa or less with a vacuum pump. Residual moisture and impurity gas are removed from the substrate 10 by heating up to 100° C.

Next, the substrate 10 is carried to a special room for growing a III-V group compound semiconductor. The temperature of the substrate 10 is heated to 500° C. while a P molecular beam is applied to the surface of the substrate 10. Thereby, an oxidized film on the surface of the substrate 10 is removed. The temperature of the substrate 10 is heated to 450° C., and Si-doped n-type InP is grown by 30 nm, thereby forming the buffer layer 11A. Then, the temperature of the substrate 10 is heated to 470° C., and Si-doped n-type InGaAs is grown by 200 nm, thereby forming the butter layer 11B.

Next, the substrate 10 is carried to a special room for growing a II-VI group compound semiconductor. The temperature of the substrate 10 is heated to 200° C. while a Zn molecular beam is applied to the surface of the buffer layer 11B, and Cl-doped n-type ZnCdSe is grown by 5 nm. Then the temperature of the substrate 10 is heated to 280° C., and Cl-doped n-type ZnCdSe is grown by 100 nm, thereby forming the buffer layer 11C. Next, under the condition where the temperature of the substrate 10 is 280° C., the superlattice of Cl-doped n-type Zn_{0.48}Cd_{0.52}Se/MgSe is grown by 1 μm, thereby forming the n-type first cladding layer 12A. Cl-doped Mg_{0.6}Zn_{0.4}Se_{0.85}Te_{0.15} is grown by 0.6 μm, thereby forming the n-type second cladding layer 12B. The superlattice of Be_{0.13}Zn_{0.87}Se_{0.40}Te_{0.60}/MgSe is grown by 70 nm, thereby forming the n-side guide layer 13. A quantum well of Be_{0.13}Zn_{0.87}Se_{0.40}Te_{0.60} (3 nm)/MgSe is grown by three layers (three wells), thereby forming the active layer 14. The superlattice of Be_{0.13}Zn_{0.87}Se_{0.40}Te_{0.60}/MgSe is grown by 70 nm, thereby forming the p-side guide layer 15. The superlattice structure of N-doped p-type Be_{0.48}Zn_{0.52}Te/MgSe is grown by 0.1 μm, thereby forming the p-type first cladding layer 16A. The superlattice of N-doped p-type Be_{0.48}Zn_{0.52}Te/Be_{0.36}Mg_{0.64}Te is grown by 0.3 μm, thereby forming the p-type second cladding layer 16B. N-doped p-type BeZnTe is grown by 30 nm, the stacked structure of N-doped p-type BeZnTe/ZnTe is grown by 500 nm, and N-doped p-type ZnTe is grown by 30 nm, thereby forming the contact layer 17.

Next, a predetermined-shaped resist pattern (not illustrated in the figure) is formed on the contact layer 17 by lithography, and a region except a region in stripe shapes where the ridge 18 is to be formed is covered. Then, by vacuum deposition, for example, a multilayer film of Pd/Pt/Au (not illustrated in the figure) is stacked on the whole surface. After this, the resist pattern and the stacked film of Pd/Pt/Au deposited on the resist pattern are lifted off. Thereby, the p-side electrode 19 is formed on the contact layer 17. After this, if necessary, the p-side electrode 19 and the contact layer 17 are in ohmic contact with each other by performing heat treatment. Next, for example, an AuGe alloy or a multilayer film of Ni/Au (not illustrated in the figure) is stacked on the whole rear surface of the substrate 10 by vacuum deposition, thereby forming the n-side electrode 20.

Next, the edge of a wafer is scratched with a diamond cutter, and the scratch is opened and divided by applying pressure, thereby cleaved. Next, a low-reflection coating (not illustrated in the figure) of approximately 5% is formed on the end face of the light emission side (front end face), and a high-reflection coating (not illustrated in the figure) of approximately 95% is formed on the end face on the opposite side from the front end face (rear end face). Chips are taken out by scratching in the stripe direction of the ridge 18.

Next, the chip is arranged on a submount (not illustrated in the figure) while the position of the light emission point and the angle of the end face are aligned, and then arranged on a heat sink (not illustrated in the figure). Next, after the p-side electrode 19 on the chip and a terminal on a stem (not illustrated in the figure) are connected with metal wire, a window cap being an exit of laser light covers the stem to perform hermetical sealing. In this manner, the laser diode 1 according to the embodiment is manufactured.

Next, operation and effects of the laser diode 1 according to the embodiment will be described.

In the laser diode 1 according to the embodiment, when a predetermined voltage is applied between the p-side electrode 19 and the n-side electrode 20, current is injected to the active layer 14, and light emission is generated by electron-hole recombination. From a section (light emission spot) corresponding to the light emission region 14A in the front end face, for example, laser light having a wavelength within a range from blue-purple to orange (480 nm to 600 nm) is emitted in the stacked plane direction.

In the embodiment, each of the n-type cladding layer 12 and the p-type cladding layer 16 is separated to two layers depending on major functions.

In the n-type first cladding layer 12A, the n-type carrier concentration is higher than that of the n-type second cladding layer 12B, and the layer thickness is larger than that of the n-type second cladding layer 12B. Thereby, the carrier conductivity of the whole n-type cladding layer 12 is maintained. In the n-type second cladding layer 12B, the bottom of the conduction band or the bottom of the sub-level of the conduction band is higher than the bottom of the conduction band or the bottom of the sub-level of the conduction band in the active layer 14. Thereby, the electron barrier which is sufficient for carrier confinement is maintained, and light emission of type II is suppressed.

On the other hand, in the p-type second cladding layer 16B, the p-type carrier concentration is higher than that of the p-type first cladding layer 16A, and the layer thickness is larger than that of the p-type first cladding layer 16A. Thereby, the p-type carrier concentration which is sufficient for the carrier conductivity is maintained. In the p-type first cladding layer 16A, the top of the valence band or the top of the sub-level of the valence band is lower than the top of the valence band or the top of the sub-level of the valence band in the active layer 14. Thereby, the hole barrier which is sufficient for the carrier confinement is maintained, and the light emission of type II is suppressed.

For these reasons, in the embodiment, it is possible that all the properties of the carrier conductivity, the carrier confinement, suppression of light emission of type II, and the light confinement are set to values appropriate for the n-type cladding layer 12 and the p-type cladding layer 16. As a result, it is possible to realize the laser diode 1 including the n-type cladding layer 12 which has properties desired in an n-type cladding layer, and the p-type cladding layer 16 which has properties desired in a p-type cladding layer.

Hereinbefore, although the present invention is described with the embodiment, the present invention is not limited to the embodiment and various modifications may be made.

For example, in the embodiment, the case where the present invention is applied to the laser diode is described. However, needless to say, the present invention is also applicable to a semiconductor device such as an LED, a photo detector (PD), or the like.

The present application contains subject matter related to that disclosed in Japanese Priority Patent Application JP 2008-207863 filed in the Japan Patent Office on Aug. 12, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising:
a semiconductor layer including an n-type first cladding layer, an n-type second cladding layer, an active layer, a p-type first cladding layer, and a p-type second cladding layer in this order on an InP substrate,
wherein the n-type first cladding layer and the n-type second cladding layer satisfy formulas (1) to (4) below, or the p-type first cladding layer and the p-type second cladding layer satisfy formulas (5) to (8) below,
1×10¹⁷ cm⁻³≦N1≦1×10²⁰ cm⁻³ (1)
N1>N2 (2)
D1>D2 (3)
Ec1<Ec3<Ec2 (4)
1×10¹⁷ cm⁻³≦N4≦10²⁰ cm⁻³ (5)
N3<N4 (6)
D3<D4 (7)
Ev1<Ev3<Ev2 (8)
where N1 is n-type carrier concentration of the n-type first cladding layer, N2 is n-type carrier concentration of the n-type second cladding layer, D1 is layer thickness of the n-type first cladding layer, D2 is layer thickness of the n-type second cladding layer, Ec1 is a bottom of a conduction band or a bottom of a sub-level of a conduction band in the n-type first cladding layer, Ec2 is a bottom of a conduction band or a bottom of a sub-level of a conduction band in the n-type second cladding layer, Ec3 is a bottom of a conduction band or a bottom of a sub-level of a conduction band in the active layer, N3 is p-type carrier concentration of the p-type first cladding layer, N4 is p-type carrier concentration of the p-type second cladding layer, D3 is layer thickness of the p-type first cladding layer, D4 is layer thickness of the p-type second cladding layer, Ev1 is a top of a valence band or a top of a sub-level of a valence band in the p-type first cladding layer, Ev2 is a top of a valence band or a top of a sub-level of a valence band in the p-type second cladding layer, and Ev3 is a top of a valence band or a top of a sub-level of a valence band in the active layer.

2. The semiconductor device according to claim 1,
wherein in the case where the n-type first cladding layer and the n-type second cladding layer satisfy formulas (1) to (4), the n-type first cladding layer has a single-layer structure mainly containing Mgₓ₁Znₓ₂Cd₁₋ₓ₁₋ₓ₂Se (0<x1<1, 0<x2<1, 0<1−x2-x1−x2<1), or a stacked structure mainly containing superlattice of MgSe/Znₓ₃Cd₁₋ₓ₃Se (0<x3<1), and
the n-type second cladding layer has a single-layer structure mainly containing Mgₓ₄Zn₁₋ₓ₄Seₓ₅Te₁₋ₓ₅ (0<x4<1, 0.5<x5<1), or a stacked structure mainly containing superlattice of MgSe/Mgₓ₆Zn₁₋ₓ₆Seₓ₇Te₁₋ₓ₇ (0<x6<1, 0.5<x7<1).

3. The semiconductor device according to claim 1,
wherein in the case where the p-type first cladding layer and the p-type second cladding layer satisfy formulas (5) to (8),
the p-type first cladding layer has a stacked structure mainly containing superlattice of MgSe/Beₓ₈Zn₁₋ₓ₈Te (0<x8<1), and
the p-type second cladding layer has a stacked structure mainly containing superlattice of Beₓ₉Mg₁₋ₓ₉Te/Beₓ₁₀Zn₁₋ₓ₁₀Te (0<x9<1, 0<x10<1), or a single-layer structure mainly containing Beₓ₁₁Mgₓ₁₂Zn₁₋ₓ₁₁₋ₓ₁₂Te (0<x11<1, 0<x12<1, 0<1−x11−x12<1).

4. The semiconductor device according to claim 1,
wherein the active layer has a single-layer structure mainly containing Beₓ₁₃Zn₁₋ₓ₁₃Seₓ₁₄Te₁₋ₓ₁₄ (0<x13<1, 0<x14<1), a stacked structure mainly containing superlattice of MgSe/Beₓ₁₅Zn₁₋ₓ₁₅Seₓ₁₆Te₁₋ₓ₁₆ (0<x15<1, 0<x16<1), or a stacked structure mainly containing superlattice of ZnSe/Beₓ₁₇Zn₁₋ₓ₁₇Seₓ₁₈Te₁₋ₓ₁₈ (0<x17<1, 0<x18<1).
